(19) United States
(12) Patent Application Publication
(10) Pub. No.: US 2023/0141507 A1
(43) Pub. Date: May 11, 2023

(54) ELECTRIC MOVING OBJECT GUIDING SITUATION OF WIRELESS CHARGING AND A METHOD USING THE SAME

(71) Applicants: Hyundai Motor Company, Seoul (KR); Kia Corporation, Seoul (KR)

(72) Inventor: Hye Joo LEE, Bucheon-si (KR)

(21) Appl. No.: 17/863,194

(22) Filed: Jul. 12, 2022

(30) Foreign Application Priority Data
Nov. 5, 2021 (KR) 10-2021-0151062

(51) Int. Cl. B60L 53/38; B60L 53/30; B60L 53/66; H02J 50/60; H02J 50/10; H02J 50/80; H02J 50/90

(52) U.S. Cl. CPC B60L 53/38; B60L 53/305; B60L 53/66; H02J 50/60; H02J 50/10; H02J 50/80; H02J 50/90

(57) ABSTRACT

An electric moving object guiding situation of wireless charging and a method using the same includes a power reception module unit configured to receive power through a power transmission module unit of a wireless charging device; a charging controller configured to control a charging operation and to generate data associated with information on a charging situation including charging progress information and charging obstacle information that occurs during a charging abnormality; and a processor configured to transmit data associated with the information on the charging situation so that the data is displayed on a user device.

### CROSS-REFERENCE TO RELATED APPLICATION

The present application claims priority to Korean Patent Application No. 10-2021-0151062, filed Nov. 5, 2021, the entire contents of which is incorporated herein for all purposes by this reference.

### BACKGROUND OF THE PRESENT DISCLOSURE

### Field of the Present Disclosure

The present disclosure relates to an electric moving object of guiding a situation of wireless charging and a method using the same, and more particularly, to an electric moving object guiding a wireless charging situation, in which the charging progress state of a moving object and various situations may be easily checked, and a method using the same.

### Description of Related Art

The electric vehicle is a moving object driven by electricity as power supply. A battery capable of charging power source is mounted in an electric vehicle itself, and the electric vehicle may be driven by power supply of the battery.

There are currently two conventional types of charging electric vehicles: plug-in (or cabled) charging, which directly connects an electric vehicle to a commercial power source through a charging line, and wireless charging. Compared with plug-in charging, wireless charging may not only be provided in various places free from spatial limitations but also prevent the poor charging state of the cabled method because no contact is exposed and such a risky situation as short circuit does not actually occur.

The wireless charging method charges a battery by making a current flow through electromagnetic induction. Herein, power may be supplied as a magnetic field generated at a transmission pad, which functions as a power supply unit, is induced to a reception pad connected to the battery. As the wireless charging method does not include any direct connection like in the cabled method, a poor charging state may occur frequently because of the misalignment between pads or other external environments like neighboring objects and weather. For high charging efficiency, a technique is needed for a user to check and handle more rapidly various types of situations which are likely to happen in charging a vehicle.

The information included in this Background of the present disclosure section is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an electric moving object guiding a wireless charging situation, in which a charging progress state of a moving object and various situations may be easily checked, and a method using the same.

The technical objects of the present disclosure are not limited to the above-mentioned technical objects, and other technical objects that are not mentioned will be clearly understood by those skilled in the art through the following descriptions.

According to an exemplary embodiment of the present disclosure, there is provided an electric moving object of guiding a situation of wireless charging, the electric moving object including: a power reception module unit configured to receive power through a power transmission module unit of a wireless charging device; a charging controller configured to control a charging operation and to generate data associated with information on a charging situation including charging progress information and charging obstacle information that occurs during a charging abnormality; and a processor configured to transmit data associated with the information on the charging situation so that the data is displayed on a user device.

According to the exemplary embodiment of the present disclosure in the electric moving object, the charging progress information may include charging state information, which includes a charging amount according to the charging operation, charging efficiency and an expected charging time, and pairing information between the power transmission module unit and the power reception module unit.

According to the exemplary embodiment of the present disclosure in the electric moving object, the charging obstacle information may be information indicating an element that causes temporary stop of the charging operation or charging failure by the charging abnormality.

According to the exemplary embodiment of the present disclosure in the electric moving object, the charging obstacle information may include at least one of pairing misalignment information indicating a misalignment based on location information of the power transmission module unit and the power reception module unit, pairing abnormality information caused by a poor pairing connection between the power transmission unit and the power reception unit, power transmission module abnormality information indicating an abnormal situation of the power transmission module unit, moving object abnormality information caused by a charging system abnormality of the electric moving object, power abnormality information according to power degradation of the wireless charging device, and external environment information causing the charging abnormality.

According to the exemplary embodiment of the present disclosure in the electric moving object, the electric moving object may further include an image acquisition unit configured to obtain a surround image of the electric moving object. Also, the pairing misalignment information and the power transmission module abnormality information may be provided as an image that estimates the misalignment and the abnormal situation based on the surround image which is obtained from the image acquisition unit during the charging operation.

According to the exemplary embodiment of the present disclosure in the electric moving object, the power transmission module unit may include a detector configured to detect the abnormal situation. The power transmission module unit may be further configured to transmit, to the processor, abnormal situation data associated with presence of an object on the power transmission module unit, which is detected by the detector, and with an impact on the power transmission module unit caused by the object. The processor may be further configured to identify the object from the surround image associated with the abnormal situation data. Also, the power transmission module abnormality information may be provided as an image that estimates the abnormal situation based on the identified object.

According to the exemplary embodiment of the present disclosure in the electric moving object, the processor may be further configured to display data associated with guide information resolving the stopping element on the user device, when resolving the stopping element in case of stop of charging due to the charging abnormality. When the stopping element is not resolved, the processor may be further configured to display data associated with the charging obstacle information, which causes the charging failure, on the user device.

According to the exemplary embodiment of the present disclosure in the electric moving object, the electric moving object may be configured to transmit the data associated with the information on the charging situation to a server. Also, the user device may be configured to receive the information on the charging situation, which is generated based on the data, from the server.

According to the exemplary embodiment of the present disclosure in the electric moving object, when the electric moving object enters a charging zone of the wireless charging device, the processor may be further configured to: maintain a predetermined distance to an object around the charging zone, generate information on a charging location that realizes normal pairing between the power transmission module unit and the power reception module unit, and provide the information on the charging location to any one of a display of the electric moving object and the user device.

According to the exemplary embodiment of the present disclosure in the electric moving object, the information on the charging location may be displayed to include a virtual charging park line where the electric moving object is parked within the charging zone.

According to another exemplary embodiment of the present disclosure, there is provided a method for guiding a wireless charging situation of an electric moving object, the method including: supplying power from a power transmission module unit of a wireless charging device to a power reception module unit of the electric moving object; controlling, by a charging controller of the electric moving object, a charging operation, and generating data associated with information on a charging situation including charging progress information and charging obstacle information that occurs during a charging abnormality; and transmitting, by a processor of the electric moving object, data associated with the information on the charging situation so that the data is displayed on a user device.

According to an exemplary embodiment of the present disclosure, an electric moving guiding a wireless charging situation, in which a charging progress state of a moving object and various situations may be easily checked, and a method using the same may be provided.

According to an exemplary embodiment of the present disclosure, as information for dissolving an obstacle element and a situation, which becomes an obstacle element to charging, is provided to a user device in an image type and many other types of notifications, a user becomes capable of quickly checking and handling such an obstacle element.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a view schematically illustrating an electric moving object, a gas charging device, a user device and a server communicating therewith.

FIG. 2 is a block diagram showing component modules of an electric moving object according to an exemplary embodiment of the present disclosure.

FIG. 3 is a flowchart illustrating a method of guiding a wireless charging situation of an electric moving object according to another exemplary embodiment of the present disclosure.

FIG. 4A and FIG. 4B are views exemplarily illustrating images displaying an alignment state along with location information between a power reception module unit of an electric moving object and a power transmission module unit of a wireless charging device.

FIG. 5A and FIG. 5B are flowcharts showing a process of providing charging progress information.

FIG. 6 is a view exemplarily illustrating an image displaying charging progress information.

FIG. 7A and FIG. 7B are flowcharts showing a process of providing charging obstacle information.

FIG. 8A, FIG. 8B, FIG. 8C, FIG. 8D, and FIG. 8E are views exemplarily illustrating images displaying charging obstacle information.

FIG. 9A and FIG. 9B are flowcharts showing a process of providing charging completion information.

FIG. 10 is a view exemplarily illustrating an image displaying charging completion information.

FIG. 11 is a flowchart showing a process of guiding a charging location of a moving object according to a neighboring object.

FIG. 12A and FIG. 12B are views exemplarily illustrating images displaying charging location information of a moving object.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to the accompanying drawings so that those skilled in the art may easily implement the present disclosure. However, the present disclosure may be implemented in various different ways, and is not limited to the exemplary embodiments described therein.

In describing exemplary embodiments of the present disclosure, well-known functions or constructions will be omitted in detail since they may unnecessarily obscure the understanding of the present disclosure. The same constituent elements in the drawings are denoted by the same reference numerals, and a repeated description of the same elements will be omitted.

In the present disclosure, when an element is simply referred to as being “connected to”, “coupled to” or “linked to” another element, this may mean that an element is “directly connected to”, “directly coupled to” or “directly linked to” another element or is connected to, coupled to or linked to another element with the other element intervening therebetween. Furthermore, when an element “includes” or “has” another element, this means that one element may further include another element without excluding another component unless stated otherwise.

In the present disclosure, the terms first, second, etc. are only used to distinguish one element from another and do not limit the order or the degree of importance between the elements unless specifically mentioned. Accordingly, a first element in an exemplary embodiment could be termed a second element in another exemplary embodiment of the present disclosure, exemplary embodiment of the present disclosure, and similarly, a second element in an exemplary embodiment could be termed a first element in another exemplary embodiment of the present disclosure, exemplary embodiment of the present disclosure, without departing from the scope of the present disclosure.

In the present disclosure, elements that are distinguished from each other are for clearly describing each feature, and do not necessarily mean that the elements are separated. That is, a plurality of elements may be integrated in one hardware or software unit, or one element may be distributed and formed in a plurality of hardware or software units. Therefore, even if not mentioned otherwise, such integrated or distributed embodiments are included in the scope of the present disclosure.

In the present disclosure, elements described in various embodiments do not necessarily mean essential elements, and some thereof may be optional elements. Therefore, an exemplary embodiment including a subset of elements described in an exemplary embodiment of the present disclosure is also included in the scope of the present disclosure. Furthermore, embodiments including other elements in addition to the elements described in the various embodiments are also included in the scope of the present disclosure.

The advantages and features of the present disclosure and the way of attaining them will become apparent with reference to various exemplary embodiments described below in detail. Embodiments, however, may be embodied in various forms and may not be constructed as being limited to example embodiments set forth herein. Rather, these embodiments are provided so that the present disclosure will be complete and will fully convey the scope of the present disclosure to those skilled in the art.

Hereinafter, various embodiments of the present disclosure will be described with reference to the accompanying drawings.

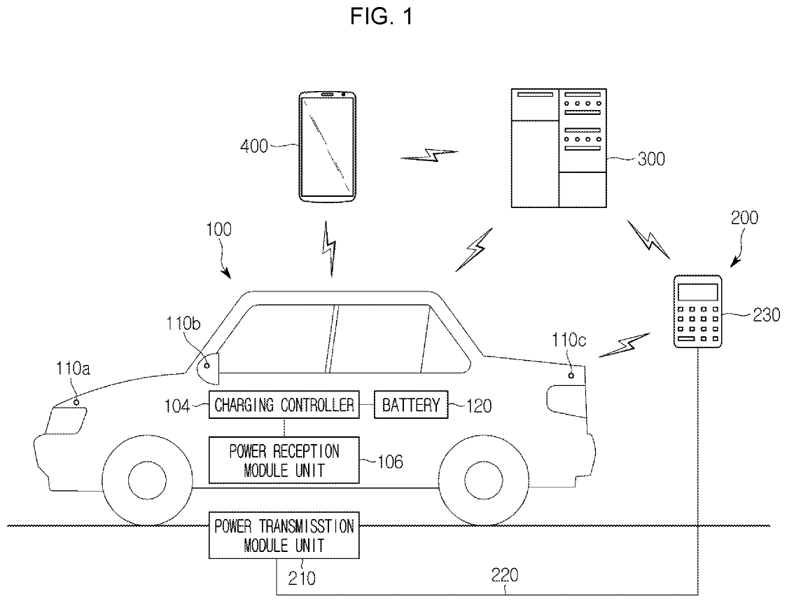

FIG. 1 is a view schematically illustrating an electric moving object, a gas charging device, a user device and a server communicating therewith.

An electric moving object 100 may be charged wirelessly by electric power from a wireless charging device 200. The electric moving object 100 may generate data associated with information on a charging situation which notifies a progress state related to a charging operation and an obstacle element and transmit the data to a server 300, and the server 300 may transmit the information on the charging situation based on the data to a user device 400. Furthermore, the electric moving object 100 may process information on a charging situation based on the data and provide the information on the charging situation to a display 114 so that the display 114 may display the information. Hereinafter the description will be presented mainly through an example of generating, by the server 300, information on a charging situation based on the data, but is not limited thereto. As an exemplary embodiment of the present disclosure, the moving object 100 may generate information on a charging situation on its own and transmit the information on the charging situation to the user device 400 with no intervention of the server 300 but by communicating directly with the user device 400. As yet another example, the moving object 100 may transmit information on a charging situation, and the information on the charging situation may be transmitted to the user device 400 via the server 300 to monitor charging states of various moving objects and identify obstacle types.

For example, the electric moving object 100 may move by use of the power of a battery 102 as a driving source and may refer to a device of which the battery 102 may be charged at least by wireless charging. The moving object 100 may be a vehicle, a personal mobility, a mobile office, or a mobile hotel. The vehicle may be a four-wheel car, for example, a sedan, a sports utility vehicle (SUV), and a pickup truck and may also be a vehicle with five or more wheels, for example, a lorry, a container truck, and a heavy vehicle. Once the moving object 100 may be driven by the battery 102 which is charged wirelessly, it may be an aerial moving object, apart from a ground moving object, for example, a drone and a personal aerial vehicle (PAV). The moving object 100 may be embodied by manned driving or autonomous driving (either semi-autonomous or full-autonomous driving). Hereinafter, for convenience of explanation, the description utilizes an example vehicle as a ground moving object but is not limited thereto, and various other types of moving objects may be applied. The moving object 100 may communicate with another device or another moving object. As an exemplary embodiment of the present disclosure, the moving object 100 may communicate with another device based on cellular communication, WAVE communication, Dedicated Short-Range Communication (DSRC) and other communication schemes. That is, as a cellular communication network, a communication network such as LTE, 5G, WiFi communication network, WAVE communication network, etc. may be used. Furthermore, a local area network used in a moving object, such as DSRC may be used, and the present disclosure is not limited to the above-described embodiment. Thus, for example, the moving object 100 may exchange data with the user device 400 and the wireless charging device 200 through short range communication and transmit and receive signals to or from the server 300 through cellular or WAVE communication.

The wireless charging device 200 may have a power transmission module unit 210, which is aligned with a power reception module unit 106 of the moving object 100 and supplies energy, a supply line 220, which supplies energy to the power transmission module unit 210, and a control panel 230 that controls energy supply through the supply line 220 and has a charge function. The power transmission module unit 210 may be located on the ground surface or be configured as a pad type, which is fixed in part on the ground surface and exposed in part, but is not limited thereto and may have any form capable of wirelessly charging the power reception module unit 106. Though not shown in the drawing, the wireless charging device 200 may include a detector for detecting an abnormal situation of the power transmission module unit 210. For example, the detector may detect whether or not there is an object on the power transmission module unit 210 and may detect an impact caused by a physical force of an external object. Accordingly, the detector may generate data of an abnormal situation which is associated with the presence of an object and an impact. As an exemplary embodiment of the present disclosure, the detector may be an object recognition detector, a pressure detector and an image detector which are embedded in the power transmission module unit 210. As an exemplary embodiment of the present disclosure, the detector may be an image detector which is provided in a location distant from the power transmission module unit 210.

Although not shown in the drawing, the wireless charging device 200 may include a module configured for communicating the moving object 100 and the user device 400 through short range communication and a module configured for communicating with the server 300. For example, the short-range communication may be based on various communication schemes like infrared communication, NFC, WiFi, Bluetooth, beacon or dedicated short range communication (DSRC). When the moving object 100 approaches a predetermined distance range of the wireless charging device 200 or approaches a charging zone as a charging space, the wireless charging device 200 may exchange data with at least one of the moving object 100 and the user device 400 through short range communication.

Communication with the server 300 may be performed through the short-range communication or a cellular communication scheme. The server 300 may be a management server for managing the wireless charging device 200 or be a moving object support server for receiving various pieces of state information of the moving object 100 and controlling and managing the moving object 100. In the present disclosure, the server 300 may receive data associated with information on a charging situation from the moving object 100, process the information on the charging situation based on the data and provide the information to the user device 400.

The user device 400 is an electronic device different from the electric moving object 100 and may be a mobile device, for example, like a smartphone and a tablet PC. To receive information on a charging situation, the user device 400 may obtain an application providing charging-related information from the server 300 and have the application embedded in it.

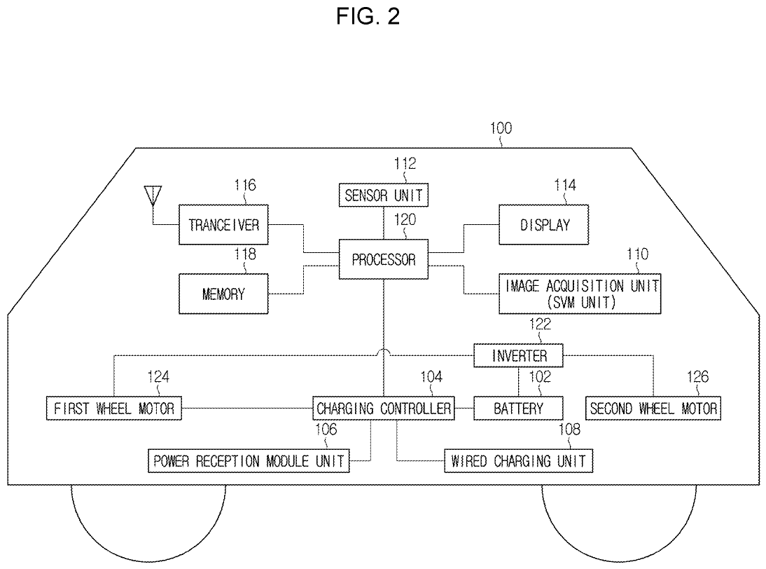

FIG. 2 is a block diagram showing component modules of an electric moving object according to an exemplary embodiment of the present disclosure.

The electric moving object 100 may have the battery 102, which supplies power to overall driving and electric devices of the moving object 100, a charging controller 104, which controls and manages a wired or wireless charging operation of the battery 102, the power reception module unit 106, which receives energy through wireless pairing with the power transmission module unit 210, and a wired charging unit 108 which is connected to a wired charger during a wired charging operation.

The charging controller 104 is configured for converting a form or value of supplied power and a function of charging-related control and may generate information on a charging situation, which includes charging progress information and charging obstacle information occurring in abnormality of charging, and relevant data.

For example, data associated with charging progress information may include charging state information, which includes a charging amount according to a charging operation, a charging efficiency and an expected charging time, and pairing information between the power transmission module unit 210 and the power reception module unit 106.

Charging obstacle information may be information indicating an element that causes temporary stop or charging failure by abnormality of charging. For example, data associated with charging obstacle information may be at least one of pairing misalignment information, pairing abnormality information, power transmission module abnormality information, moving object abnormality information, power abnormality information, and external environment information.

Pairing misalignment information may be data showing misalignment based on location information of the power transmission module unit 210 and the power reception module unit 106. Pairing abnormality information may be data associated with a poor pairing connection between the power transmission module unit 210 and the power reception module unit 106, even when they are normally aligned with each other. For example, power transmission module abnormality information may be data associated with lowering charging efficiency caused by the presence of an object and an impact on the power transmission module unit 210. Moving object abnormality information may be an abnormality of a charging system of the electric moving object 100. Power abnormality information may be data associated with low power supply caused by power degradation of a wireless charging device. External environment information may be data associated with temperatures of the charging zone 240, weather information (e.g., snow, fine dust, rainfall) at the time of charging, and other various external factors that become obstacles to wireless charging.

Meanwhile, for example, in case of wireless charging, the charging controller 104 may have a wireless charge converter unit (WCCU). As an exemplary embodiment of the present disclosure, the charging controller 104 may be a functional module included in a vehicle charging management system (VCMS) or a battery management system (BMS), which executes integrated charging management and control for the battery 102. As yet another example, the charging controller 104 may be a function included in a vehicle control unit (VCU) which performs overall management and control of the moving object 100. The charging controller 104 is not limited to the above-described examples and may operate by being integrated with the processor 120. The power reception module unit 106 may be configured as a pad type which is exposed or embedded on a bottom surface of the moving object 100.

The electric moving object 100 may include an image acquisition unit 100 configured to obtain image information around the moving object, a sensor unit 112 configured to detect various states other than visual information, a display 114, a transceiver 116 configured to exchange a signal with an external device (e.g., the wireless charging device 200, the server 300, the user device 400), a memory 118, and the processor 120.

The image acquisition unit 110 may include front, side and rear cameras 110a, 110b and 110c for obtaining front, rear, left and right side-view images of the moving object 100. Thus, the image acquisition unit 110 may provide images obtained from each of the cameras 110a, 110b and 110c to the processor 120, and the processor 120 may combine each image and display surround image information on the display 114. For example, the surround image information may be provided in a form of surround view monitor (SVM) on the display 114. The sensor unit 112 may include a Global Positioning System (GPS) detector, a velocity detector, an IMU or INS detector, a distance detector, a proximity recognition detector, a temperature/humidity detector, and a detector for measuring various systems or detecting system conditions in the moving object 100.

The processor 120 performs overall control of the electric moving object 100 and may transmit data associated with information on a charging situation during wireless charging to the server 300 so that the data may be displayed on the user device 400. Furthermore, the processor 120 may be configured to generate information on a charging situation from the data and to display the information on the display 114.

The electric moving object 100 may include an inverter 122, which converts a particular type of power of the battery 102 into another type and reduces voltage, and first and second wheel motors 124 and 126 configured to drive by receiving power from the inverter 122.

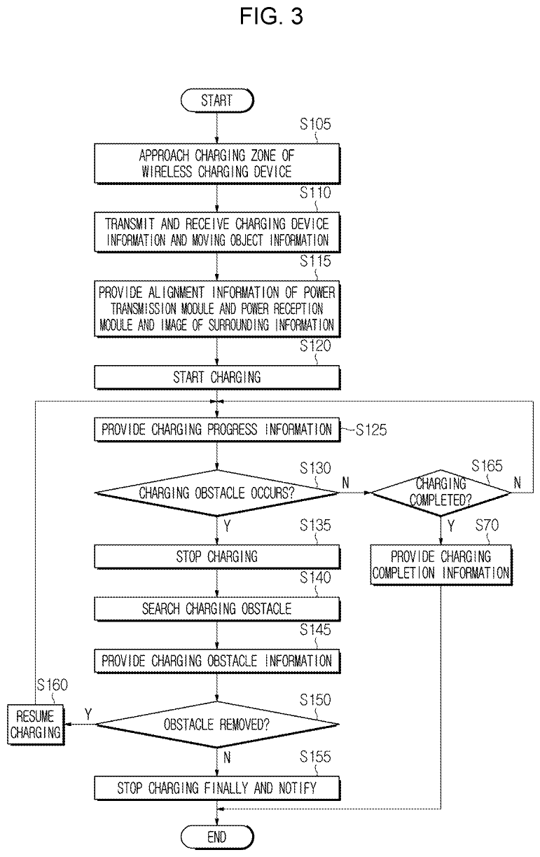

FIG. 3 is a flowchart illustrating a method of guiding a wireless charging situation of an electric moving object according to another exemplary embodiment of the present disclosure. Hereinafter, the description will be presented mainly through an example of providing information on a charging situation, which is derived from a charging operation, to the user device 400 and the display 114 of the moving object 110 via the server 300. However, the present disclosure is not limited thereto, but as an exemplary embodiment of the present disclosure, information on a charging situation may be provided only to the user device 400 or only to the display 114. As yet another example, information on a charging situation may be generated in the moving object 100 or the wireless charging device 200 and be provided to at least one of the user device 400 and the display 114. Unless technically inconsistent, the description below may be applied to the above-described another example actually in the same way.

First, the electric moving object 100 may approach a charging zone of the wireless charging device 200 (S105).

When the moving object 100 approaches the charging zone, the moving object 100 may enable communication with the wireless charging device 200 by transmitting an access request message through the transceiver 116. Furthermore, when the server 300 is a server for supporting a moving object, the moving object 100 may transmit location information to the server 300 so that the server 300 may check whether or not the moving object is approaching the wireless charging device 200. When the server 300 is a management server of a charging device, the moving object 100 may be connected to the server 300 through the wireless charging device 200.

Next, the moving object 100 may transmit information on the moving object to the wireless charging device 200, and the wireless charging device 200 may transmit information on the charging device to the moving object 100 (S110).

Through exchange of identification information and authentication information between the moving object 100 and the wireless charging device 200, the wireless charging device 200 may identify and authenticate the moving object 100 configured for a charging service.

Information on a moving object may include identification information of the moving object, authentication information, a communication setting with the wireless charging device 200, location information of the power reception module unit 106, a charging specification, and a residual amount. Herein, for example, the identification information of the moving object may include an ID uniquely assigned to each moving object, a type of the moving object, and an age. When surround image information is displayed on the display 114 or the user device, the location information of the power reception module unit 106 may be converted and set to a location of a corresponding screen to be displayed on a predetermined portion of the moving object 100, which is virtually shown. For example, the charging specification may be a total battery capacity of the moving object 100, a state of health (SoH), a permissible value of energy which may be received per unit time, and a state of a charging system.

Information on a charging device may include device identification information, authentication information, and device specification information. For example, the device specification information may include a type of the moving object 100 either capable or incapable of a charging service, location information of the power transmission module unit 210, suppliable charging power, and state information of the power transmission module unit 210. The location information of the power transmission module unit 210 may be location data within a charging zone. For example, when the moving object 100 enters the charging zone and a screen of the display 114 or the user device 400 is enabled, the wireless charging device 200 may transmit the location information of the power transmission module unit 210 to the moving object 100 so that the location information of the power transmission module unit 210 may be matched with the location information of the power reception module unit 106 and be displayed on the screen. Each piece of the location information is set based on the charging zone, the location information of the power transmission module unit 210 may be converted to a screen location, which is similar to the power reception module unit 106, to be displayed on the screen. The state information of the power transmission module unit 210 corresponds to various types of state data of the power transmission module unit 210 affecting an energy transmission operation and may be data of a situation in which such external factors as a neighboring object, a weather condition and particulate matters are affecting the power transmission module unit 210.

Next, the moving object 100 may provide not only the location information of the power transmission module unit 210 and the power reception module unit 106 but also alignment information based on the location information through the display 114 and also provide surrounding information of the moving object 100 in an image form (S115).

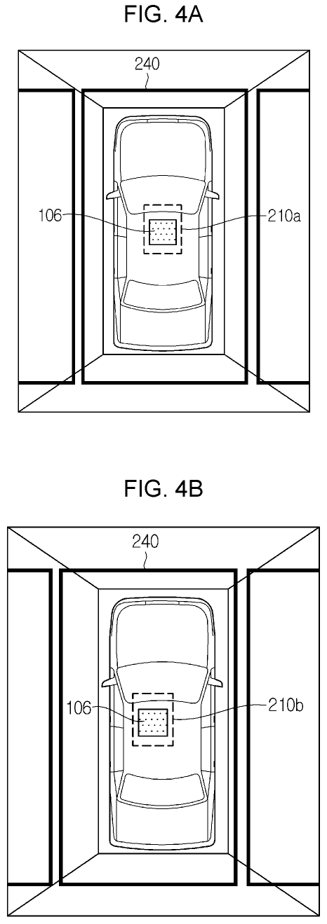

The moving object 100 may receive the location information of the power transmission module unit 210 from the wireless charging device 200, and as illustrated in FIG. 4A and FIG. 4B, may obtain surround image data including the charging zone 240, which the moving object 100 enters, and the power transmission module unit 210. FIG. 4A and FIG. 4B are views exemplarily illustrating images displaying an alignment state along with location information between a power reception module unit of an electric moving object and a power transmission module unit of a wireless charging device. In addition to this, the processor 120 of the moving object 100 may be configured to synthesize image data, which virtually represent the entering moving object 100, with the surrounding image data and to display image information thus synthesized on the display 114, as shown in FIG. 4A and FIG. 4B. Virtual image data may be processed to represent location information of the power reception module unit 106. In the above example, alignment information is shown on the display 114 of the moving object 100 but is not limited thereto and may be shown on the user device 400.

In FIG. 4A and FIG. 4B, it is illustrated that alignment information with the power transmission module unit 210 is provided as an image according to the power reception module unit 106 which is placed at different locations according to the moving object 100. The moving object 100 may store location information 210a and 210b of each power reception module unit 106. When the moving object 100 approaches the wireless charging device 200, the processor 120 may obtain an image associated with the charging zone 240 and the location information of the power transmission module unit 210 and may generate alignment information matching unique location information of the power reception module unit 106.

Though not shown in FIG. 4A and FIG. 4B, the moving object 100 analyzes the alignment information, and when both module units 106, 210a and 210b are aligned within a range satisfying predetermined charging efficiency, the processor 120 may forward an alignment state configured for charging to the display 114 or the user display 400.

Next, the moving object 100 or the user device 400 may receive a command associated with the start of charging from a user and transmit the command to the wireless charging device 200 so that the wireless charging device 200 may start a charging operation (S120).

The user may input a request message including at least one of a target charging amount and an expected charging time through at least one of the moving object 100 and the user device 400, and the wireless charging device 200 may start charging according to the request message. The request message may include a request for information on a charging situation, which is provided to the user device 400, and may be transmitted to the wireless charging device 200 via the server 300. In the instant case, when receiving the request message, the server 300 may request the processor of the moving object 100 to transmit data associated with the information on the charging situation and may receive and accumulate the data to monitor and manage a charging operation. Furthermore, the wireless charging device 200 may determine, according to a charging specification of the moving object 100, whether or not the user's request is satisfied and may perform a charging operation which is determined according to a result of determination.

Next, the server 300 may provide charging progress information to the user device 400 (S125).

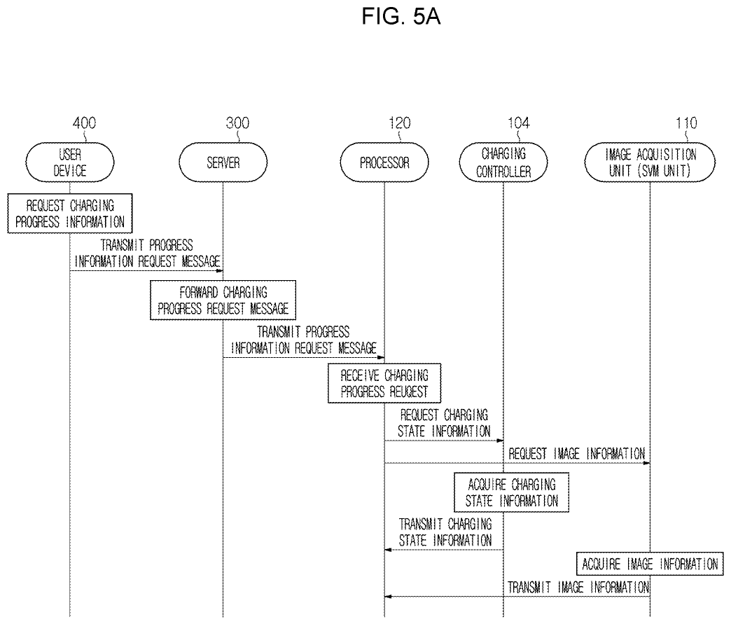

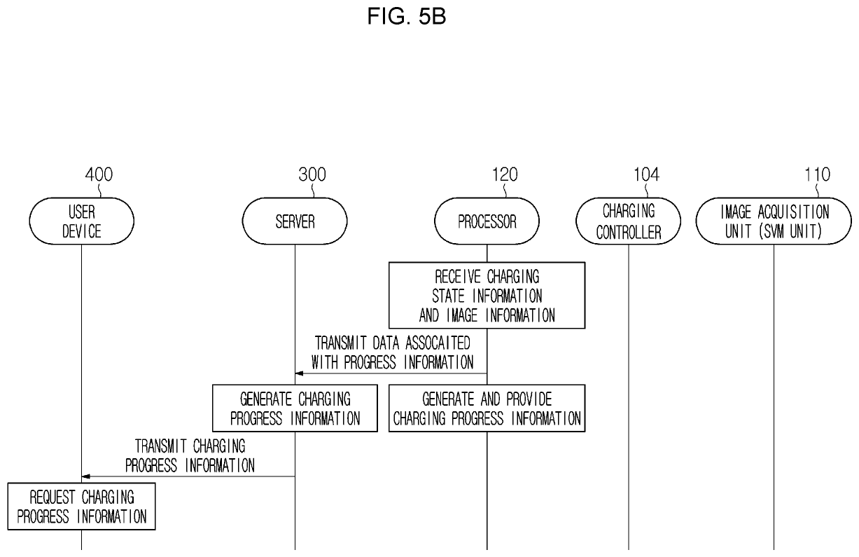

Step S125 will be described with reference to FIG. 5A and FIG. 5B. FIG. 5A and FIG. 5B are flowcharts showing a process of providing charging progress information.

As described at step S120, the user device 400 may request information on a charging situation to the server 300. Information on a charging situation may include charging state information according to a charging operation, charging progress information including pairing information, and charging obstacle information that occurs due to charging abnormality. When no charging abnormality occurs during a charging operation, the information on a charging situation may include charging progress information. During normal charging, the information on a charging situation requested by the user device 400 may be actually charging progress information.

The server 300 may receive a request message of charging progress information and transmit the request message to the processor 120 of the moving object 100. When receiving the message, the processor 120 may request information on a charging situation to the charging controller 104 and request a pairing state and a surround view image during a charging operation to the image acquisition unit 110.

The charging controller 104 may monitor the intensity and state of energy, which is supplied from the power transmission module unit 210 to the power reception module unit 106, in real time and determine a cumulative charging amount, an expected residual charging time, and charging efficiency. Furthermore, the charging controller 104 may monitor a pairing state between both module units in real time according to a communication condition, an external object and weather. Accordingly, the charging controller 104 may generate data associated with charging state information by checking a charging state and a pairing state.

The charging controller 104 may obtain a surround image and a change of alignment state between both module units according to a movement of the moving object 100 during a charging operation in real time from the image acquisition unit 110. The surround image may be generated to detect an external object affecting the charging operation. The charging controller 104 may process image information to include all the surround image and alignment states.

The charging controller 104 may transmit data associated with charging state information and image information to the processor 120, and the processor 120 may be configured to transmit data associated with charging progress information including the data and the image information to the server 300. Herein, the data associated with the charging progress information may be transmitted as the above-described data and information as they are, or may be transmitted as charging progress information which is generated or processed based on the data.

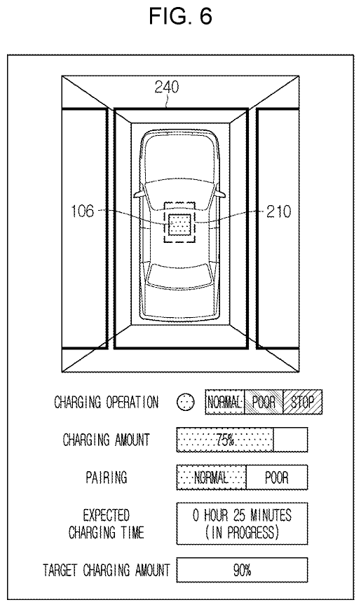

The server 300 may receive the data associated with charging progress information and generate or process the data as charging progress information. The server 300 may transmit the charging progress information to the user device 400 in real time and provide the information as illustrated in FIG. 6. FIG. 6 is a view exemplarily illustrating an image displaying charging progress information. Referring to FIG. 6, for example, charging progress information may include charging state information which provides whether or not a charging operation is in progress and whether or not the charging operation is normal, a current charging amount relative to a target charging amount, and an expected residual time to the target charging amount on a user-friendly interface. Furthermore, the charging progress information may be image information which is provided in a form of surround view in real time, and the image information may include surround image information and alignment state information between both module units. For example, the alignment state information may be generated as an alignment image of location information between the power transmission module unit 210 and the power reception module unit 106 within the charging zone 240. The surround image information may be an omnidirectional image encompassing the moving object 100 and the charging zone 240 so that influential factors of a charging operation like an external object and a weather condition may be checked in real time.

Referring to FIG. 3 again, the moving object 100 may check whether or not a charging abnormality occurs during a charging operation (S130), and when the abnormality exists (Y of S130), at least one of the moving object 100 and the wireless charging device 200 may stop charging (S135). Next, the moving object 100 may search for a charging obstacle element that causes the stop of charging (S140).

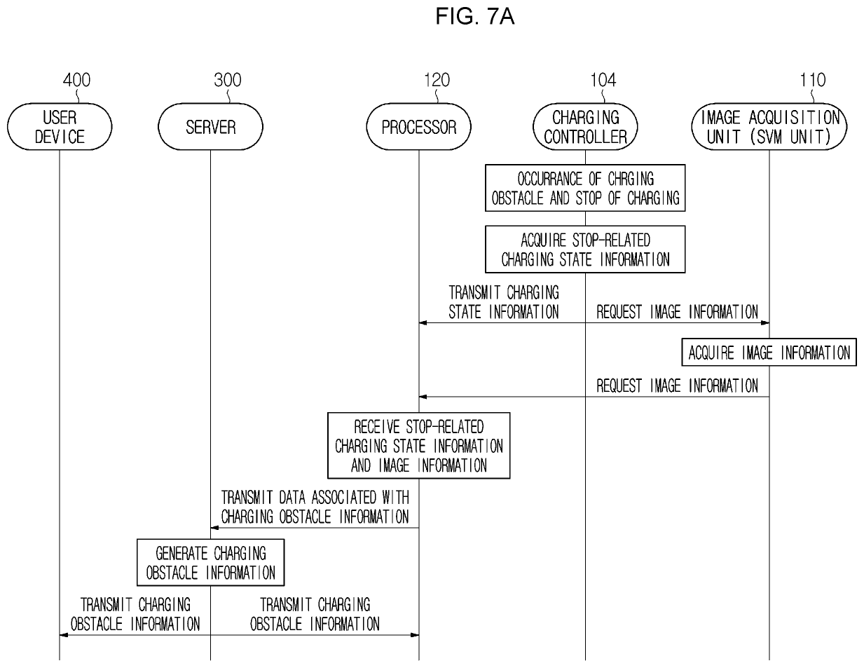

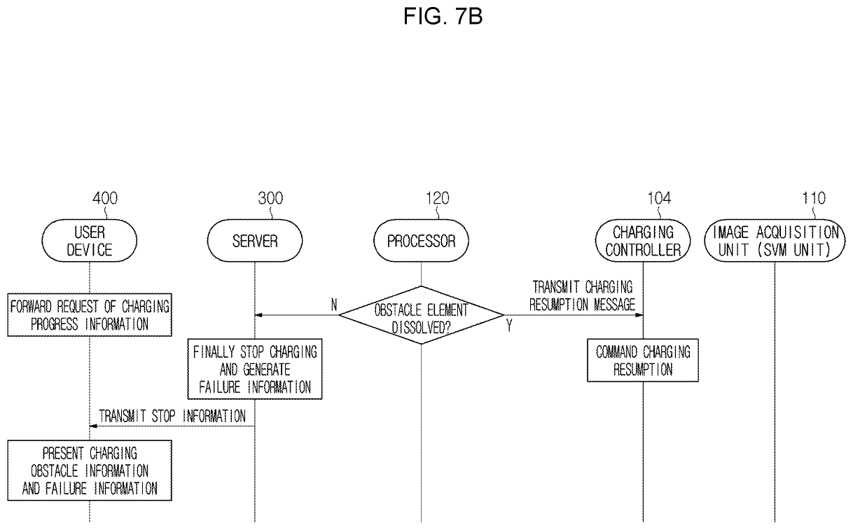

Step S130 to step S140 will be described with reference to FIG. 7A and FIG. 7B. FIG. 7A and FIG. 7B are flowcharts showing a process of providing charging obstacle information.

When receiving data associated with charging progress information during a charging operation, the charging controller 104 of the moving object 100 may monitor data associated with progress information like the intensity of energy supplied to the power reception module unit 106, an energy state, a pairing state and charging efficiency. When, as a monitoring result, at least one of the energy intensity, the energy state, the pairing state and the charging efficiency is equal to or less than a threshold or is a specific energy state, the charging controller 104 or the wireless charging device 200 may stop wireless charging.

Subsequently, the charging controller 104 may analyze data associated with progress information causing the stop of charging and obtain charging state information associated with the stop. The charging controller 104 may search for an element, which actually causes the stop of charging, among obstacle elements based on the data associated with the progress information. An obstacle element may be an external environment including temperatures, weather situations and the like, which cause a pairing misalignment between both module units 106 and 210, pairing abnormality information caused by poor pairing connection during energy transmission, a transmission module abnormality, a charging system abnormality of the moving object 100, degradation of power supplied from the wireless charging device 200, and significant degradation of charging efficiency.

Pairing misalignment may occur as early as before the start of charging or may occur as the moving object 100 moves during a charging operation after being correctly aligned. Pairing misalignment may be recognized as a change of alignment state between both module units, which is estimated from the image acquisition unit 110. Data associated with the power transmission module abnormality may be obtained through a detector of the wireless charging device 200, the image acquisition unit 110 of the moving object 100, and the sensor unit 112. The presence of an object and an impact on the power transmission module unit 210 may be recognized through detected data of the detector and the sensor unit 112, which are detected during the degradation of charging efficiency, and a surround image which is obtained from the image acquisition unit 110 at the time of the degradation. The external environment may be checked based on weather data which are transmitted from a temperature-humidity detector of the sensor unit 112 and the server 300.

Next, the charging controller 104 may collect charging state information associated with stop and transmit the information to the processor 120. Furthermore, when image information, in which pairing misalignment and power transmission module abnormality may be identified, is included in the information associated with stop, the charging controller 104 may request and obtain a surround view type of image information at the time of stop of charging from the image acquisition unit 110. The charging controller 104 may receive image information and transmit the image information together with charging state information associated with stop to the processor 120.

Referring to FIG. 3 again, the processor 120 may transmit the stop-related information and the image information to the server 300, and the server 300 may generate or process charging obstacle information based on the information and provide the charging obstacle information to the user device 400 (S145). In the instant case, the processor 120 may generate charging obstacle information based on the stop-related information and the image information and provide the charging obstacle information in a similar form to the user device to the display 114.

Next, at least one of the user, the moving object 100 and the wireless charging device 200 may try a measure to dissolve an obstacle element by referring to the charging obstacle information, and based on the measure, at least one of the moving object 100 and the wireless charging device 200 may determine whether or not a charging resumption state is reached. That is, it may be determined whether or not the obstacle element according to the measure is dissolved (S150).

When the measure is not implemented or an implemented measure is not sufficient to dissolve the obstacle element, at least one of the moving object 100 and the wireless charging device 200 may finally stop wireless charging, and the server 300 may receive a final stop message from the moving object 100 and transmit failure information to the user device 400 (S155). The server 300 may include charging obstacle information causing the failure among the pre-stored pieces of information in the failure information and transmit the information to the user device 400. In the instant case, the server 300 or the processor 120 may provide the failure information through the display 114.

On the other hand, when it is determined that the measure dissolves the obstacle element, at least one of the moving object 100 and the wireless charging device 200 may resume wireless charging, and the processor 120 may provide not only charging resumption information but also charging progress information due to resumption to the server 300 and the display 114. The server 300 may process the information to be transmitted to the user device.

Step S145 to step S160 will be described with reference to FIG. 7A and FIG. 7B.

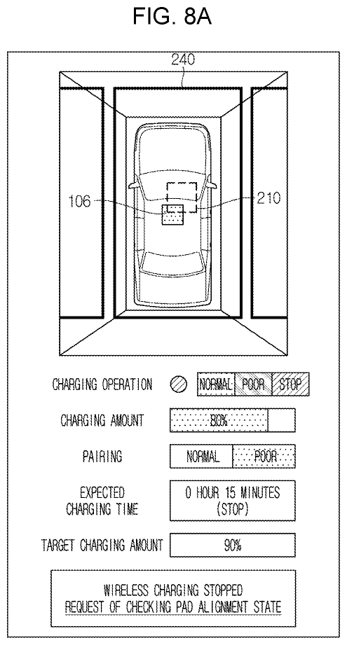

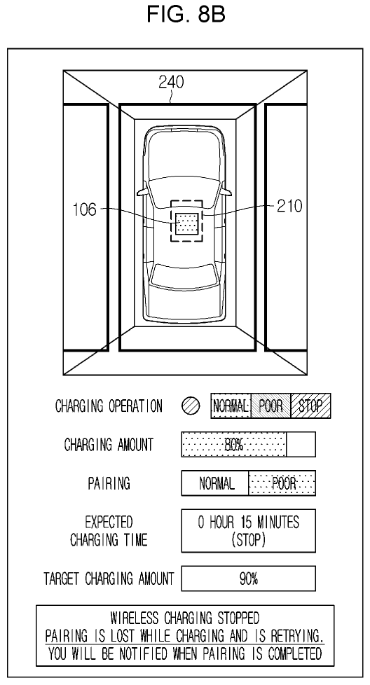

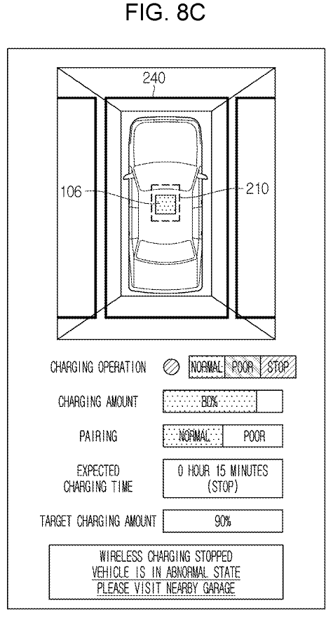

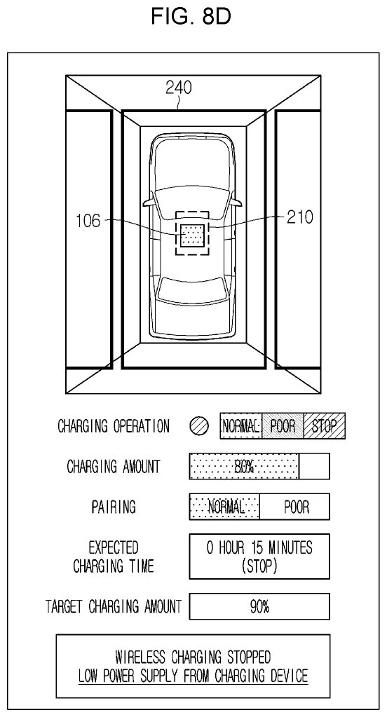

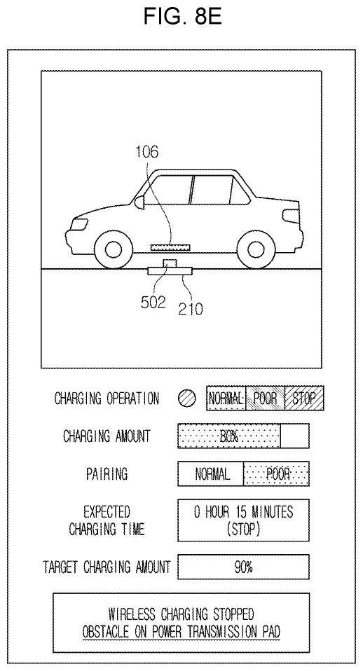

The processor 120 may receive and transmit stop-related charging state information and/or image information to the server 300. Next, the server 300 may generate or process charging obstacle information based on the information and transmit the charging obstacle information to the user device 400. As illustrated in FIG. 8A, FIG. 8B, FIG. 8C, FIG. 8D, and FIG. 8E, the user device 400 may show the charging obstacle information to a user according to a type of an obstacle element. The charging obstacle information may also be provided to the display 114 in a similar to FIG. 8A, FIG. 8B, FIG. 8C, FIG. 8D, and FIG. 8E.

FIG. 8A, FIG. 8B, FIG. 8C, FIG. 8D, and FIG. 8E are views exemplarily illustrating images displaying charging obstacle information.

FIG. 8A shows temporary stop of charging corresponding to a case in which charging obstacle information is a pairing misalignment between both module units 106 and 210. The charging obstacle information may not only present a charging amount before the stop of charging and an expected residual charging time but also mark a current suspended state of charging as ‘stop’. In the present drawing, the suspended state is marked in a different color from the color of normal or poor charging but is not limited thereto. The suspended state may be provided by various interface forms which enable users to perceive stop of charging. A poor state may be presented when charging is not suspended but performed with low efficiency. Though not shown in FIG. 8A, FIG. 8B, FIG. 8C, FIG. 8D, and FIG. 8E, by the moving object 100 and the server 300, information on poor charging, which indicates an obstacle element causing a poor state, may be provided to the user device 400.

For the user's intuitive understanding, as in FIG. 8A, obstacle information associated with pairing misalignment may be indicated by a misalignment state image and a surround image based on the location information of both module units 106 and 210 in a surround view mode. Furthermore, charging obstacle information may provide guide information for dissolving pairing misalignment as well as pairing misalignment information. In the case of FIG. 8A, to dissolve a stopping element (or obstacle element) like pairing misalignment, guide information may provide a ‘pad alignment state check request’ message and a current alignment state between both module units 106 and 210. By referring to the guide information, the user may take a necessary measure for pairing alignment configured for charging.

FIG. 8B shows temporary stop of charging corresponding to a case in which charging obstacle information is a pairing abnormality caused by a poor pairing connection between both module units 106 and 210. The charging obstacle information may present ‘stop’ of operation state, a current charging amount, an expected residual charging time, and a pairing abnormality state caused by a poor connection. To dissolve an obstacle element like a pairing abnormality, guide information may be provided in a form of message that the moving object 100 is trying a normal pairing connection again and the user may stand by until the normal pairing connection is completed.

FIG. 8C shows stop of charging corresponding to a case in which charging obstacle information is an abnormality of the moving object 100 caused by a charging system abnormality of the moving object 100. The charging obstacle information may present ‘stop’ of operation state, a current charging amount, an expected residual charging time, and an abnormal state of the moving object. Besides, guide information may recommend the maintenance of the moving object to dissolve an obstacle element like an abnormality of the moving object.

FIG. 8D shows stop of charging corresponding to a case in which charging obstacle information is an abnormality of power caused by power degradation of the wireless charging device 200. The charging obstacle information may present ‘stop’ of operation state, a current charging amount, an expected residual charging time, and an abnormal state of power supply.

FIG. 8E shows temporary stop of charging corresponding to a case in which charging obstacle information is an abnormality of a power transmission module indicating an abnormal state of the power transmission module unit 210. The charging obstacle information may present, for example, ‘stop’ of operation state, a current charging amount, an expected residual charging time, and the presence of an external object on the power transmission module unit 210. For example, the external object, which is a moving object, may be an object which is moved by an external force or external control. For the user's intuitive understanding, obstacle information associated with the presence of an object may be marked as a virtual image in which another object exists between both module units 106 and 210. To dissolve an obstacle element like the presence of an object, guide information may provide a message about the presence of obstacle, and the user may take a measure to remove the obstacle by referring to the guide information.

Referring to FIG. 7 again, the processor 120 may determine whether or not the resumption state of charging is reached by determining whether or not an obstacle element is dissolved d according to the guide information exemplified in FIG. 8A, FIG. 8B, FIG. 8C, FIG. 8D, and FIG. 8E.

When the measure is not implemented at all or when a measure thus implemented is not sufficient, the processor 120 may finally stop wireless charging, and the server 300 may receive a final stop message and transmit failure information to the user device 400. In the example of FIG. 8B, when the moving object 100 tries a normal pairing connection repeatedly but no normal pairing is achieved within a predetermined time or a predetermined number of times, the processor 120 may determine that the resumption state of charging cannot be reached. The processor 120 may request final stop of charging through the charging controller 104 and transmit a final stop message to the server 300. Based on the message, the server 300 may change the operation state from temporary stop to final stop of charging and generate failure information accordingly. The server 300 may transmit the failure information to the user device 400. In the example of FIG. 8B, failure information may indicate that charging obstacle information causing charging failure is a poor pairing connection and the charging service is not provided due to the poor pairing connection. Accordingly, the temporary stop screen of the FIG. 8B may be modified to indicate that the charging operation fails and the charging obstacle information is poor pairing.

In the above example, guide information includes an appropriate measure and thus checks whether or not the measure is completely implemented and transmits failure information. As an exemplary embodiment of the present disclosure, guide information may not provide a measure to remove an obstacle element in a short time. Like in FIG. 8C and FIG. 8D, when charging obstacle information is information on an abnormality of a moving object or information on a power abnormality, the processor 120 may be configured to skip a checking process for removing an obstacle element, to finally stop charging and to transmit a final stop message to the server 300. Thus, the server 300 may transmit not charging obstacle information according to temporary stop but failure information to the user device 400. The temporary stop screens of FIG. 8C and FIG. 8D may be modified to indicate that the charging operation fails and the charging obstacle information is an abnormality of moving object and a very low level of external power supply.

On the other hand, when it is determined that the measure dissolves the obstacle element, the moving object 100 may resume wireless charging, the processor may provide not only charging resumption information but also charging progress information due to resumption to the user device 400 via the server 300.

Referring to FIG. 3 again, when it is confirmed by the moving object 100 that no abnormality of charging occurs (N of S130), the moving object 100 may determine whether or not wireless charging is completed in accordance with the user's charging request (S165). When it is determined that the charging is completed, the moving object 100 may transmit data associated with charging completion information via the server 300 (S170). At the instant time, the moving object 100 may transmit the data to the display 114.

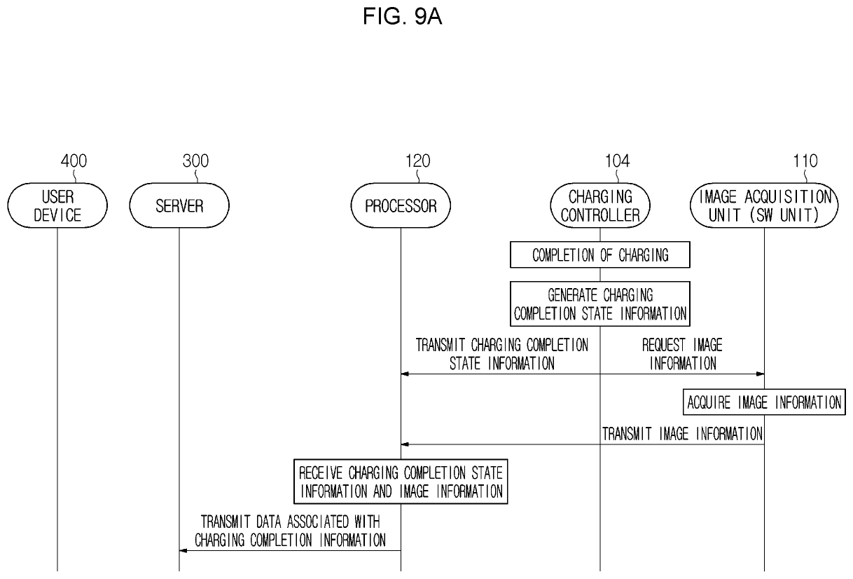

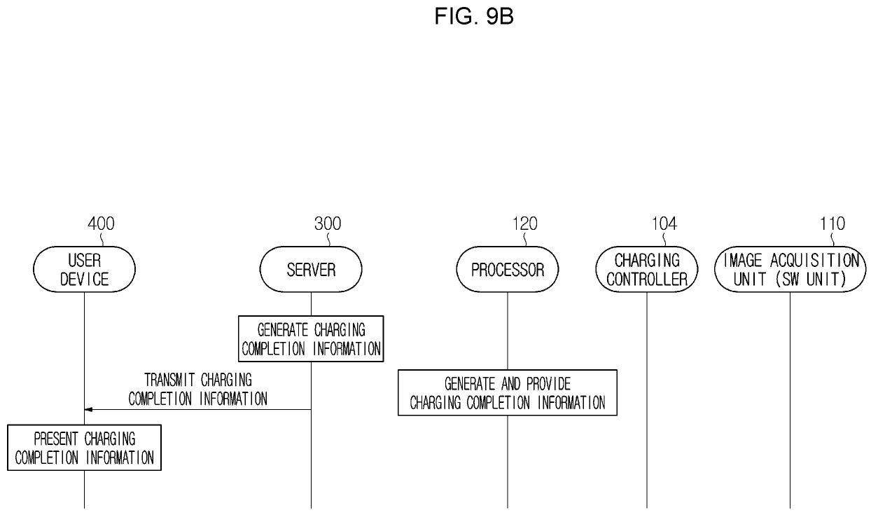

Step S170 will be described with reference to FIG. 9A and FIG. 9B. FIG. 9A and FIG. 9B are flowcharts showing a process of providing charging completion information.

When charging is completed, the charging controller 104 may generate information on a charging completion state. The information on a charging completion state may include a target charging amount, a completed charging amount, an available travel distance and the like. Furthermore, the charging controller 104 may request image information including a pairing state between both module units at the time of charging completion and a surround image in a form of surround view. Under the control of the processor 120, the charging controller 104 may transmit data associated with charging completion information including information on a charging completion state and image information to the server 300. Herein, the data associated with the charging completion information may be transmitted as the above-described state and information as they are, or may be transmitted as charging completion information which is generated or processed based on the data.

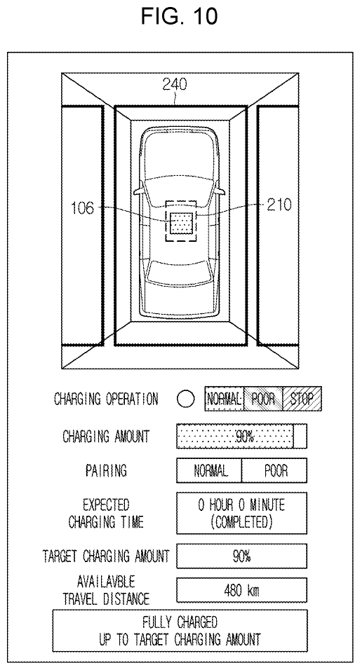

The server 300 may receive the data associated with charging completion information and process the data as charging completion information. The server 300 may transmit the charging completion information to the user device 400, and the user device 400 may provide the charging completion information as exemplified in FIG. 10. FIG. 10 is a view exemplarily illustrating an image displaying charging completion information. Referring to FIG. 10, for example, charging completion information may provide completion of a charging operation, a target charging amount, a completed charging amount, an available travel distance and the like to a user-friendly interface. In FIG. 10, an expected residual charging time is exemplified as 0, but a required charging time may be provided. Furthermore, image information may include surround image information and alignment state information between both module units.

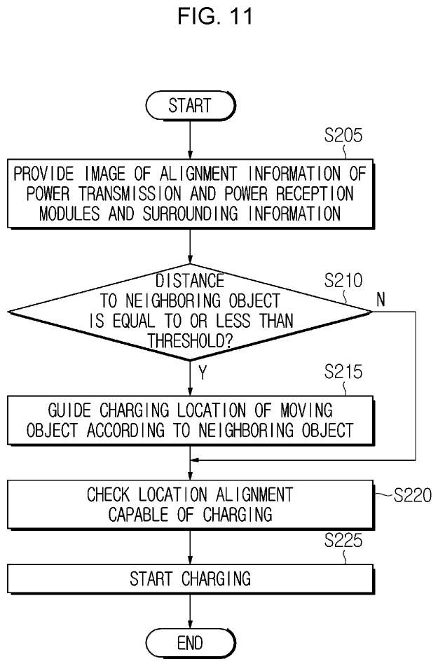

FIG. 11 is a flowchart showing a process of guiding a charging location of a moving object according to a neighboring object.

FIG. 11 relates an exemplary embodiment where an optimal charging location is guided in case a constraint on alignment between both module units 106 and 210 exists due to a neighboring object while the moving object 100 enters the charging zone 240.

First, like in step S115 of FIG. 3, the moving object 100 may provide not only the location information of the power transmission module unit 210 and the power reception module unit 106 but also alignment information based on the location information through the display 114 and also provide surrounding information of the moving object 100 in an image form (S205).

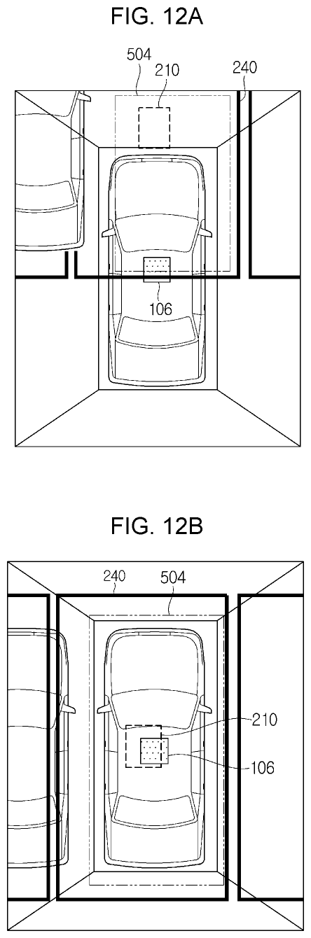

Next, at least one of the image acquisition unit 110 and the sensor unit 112 may detect a neighboring object around the charging zone 240 and determine whether or not a distance to the neighboring object (which is exemplified as another moving object around the charging zone 240 in FIG. 12A) is equal to or less than a threshold (S210).

Distance measurement through the image acquisition unit 110 may estimate a distance between a neighboring object and the moving object 100 through an image analysis according to machine learning for the neighboring object, which is obtained from a surround image, and the moving object 100. As an exemplary embodiment of the present disclosure, a distance detector and a proximity recognition detector, which are mounted in the sensor unit 112, may measure a distance to a neighboring object. As yet another example, a distance may be estimated by a combination of the above-described examples.

As a result of determination, when a separation distance between the moving object 100 and a neighboring object is equal to or less than a threshold, the processor 120 may maintain a predetermined distance between the charging zone 240 and the neighboring object and generate information on a charging location that realizes normal pairing between the power transmission module unit 210 and the power reception module unit 106.

The processor 120 may check location information of the power reception module unit 106, and based on charging specification information of the moving object 100 and specification information of the wireless charging device 200, may also check an overlapping region between the power transmission and reception module units 210 and 106 configured for normal pairing. When there is an overlapping region, as shown in FIG. 12A, the processor 120 may process image information so that a virtual charging park line corresponding to the overlapping region may be generated in image information including the location information of both the module units 106 and 210 and a surround image. FIG. 12A and FIG. 12B are views exemplarily illustrating images displaying charging location information of a moving object. The processor 120 may transmit image information to at least one of the display 114 and the user device 400.

Next, while checking the charging park line represented as an image, a user may move the moving object 100 to the charging zone 240, as shown in FIG. 12B. Based on mobile image information of the moving object 100, which is obtained in real time, the processor 100 check the alignment state of the power reception module unit 106 relative to the power transmission module unit 210, and when a location alignment configured for charging is achieved, may give a location alignment message to the user (S220).

Next, the user may confirm the location alignment message thus notified and transmit a command associated with start of charging to the moving object 100 or the user device 400 (S225). The command is transmitted to the wireless charging device 200, and the wireless charging device 200 may start a charging operation.

While the exemplary methods of the present disclosure described above are represented as a series of operations for clarity of description, it is not intended to limit the order in which the steps are performed, and the steps may be performed simultaneously or in different order as necessary. To implement the method according to an exemplary embodiment of the present disclosure, the described steps may further include other steps, may include remaining steps except for some of the steps, or may include other additional steps except for some of the steps.

The various embodiments of the present disclosure are not a list of all possible combinations and are intended to describe representative aspects of the present disclosure, and the matters described in the various embodiments may be applied independently or in combination of two or more.

Furthermore, various embodiments of the present disclosure may be implemented in hardware, firmware, software, or a combination thereof. In the case of implementing the present disclosure by hardware, the present disclosure may be implemented with application specific integrated circuits (ASICs), Digital signal processors (DSPs), digital signal processing devices (DSPDs), programmable logic devices (PLDs), field programmable gate arrays (FPGAs), general processors, controllers, microcontrollers, microprocessors, etc.

The scope of the present disclosure includes software or machine-executable commands (e.g., an operating system, an application, firmware, a program, etc.) for facilitating operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. Included in the specification mean units for processing at least one function or operation, which may be implemented by hardware, software, or a combination thereof.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described to explain certain principles of the present disclosure and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An electric moving object of guiding a situation of wireless charging, the electric moving object comprising:
a power reception module unit configured to receive power through a power transmission module unit of a wireless charging device;
a charging controller configured to control a charging operation and to generate data associated with information on a charging situation including charging progress information and charging obstacle information that occurs during a charging abnormality; and
a processor configured to transmit data associated with the information on the charging situation so that the data is displayed on a user device.

2. The electric moving object of claim 1, wherein the charging progress information includes charging state information, which includes a charging amount according to the charging operation, charging efficiency and an expected charging time, and pairing information between the power transmission module unit and the power reception module unit.

3. The electric moving object of claim 1, wherein the charging obstacle information is information indicating an element that causes temporary stop of the charging operation or charging failure by the charging abnormality.

4. The electric moving object of claim 3, wherein the charging obstacle information includes at least one of pairing misalignment information indicating a misalignment based on location information of the power transmission module unit and the power reception module unit, pairing abnormality information caused by a poor pairing connection between the power transmission unit and the power reception unit, power transmission module abnormality information indicating an abnormal situation of the power transmission module unit, moving object abnormality information caused by a charging system abnormality of the electric moving object, power abnormality information according to power degradation of the wireless charging device, and external environment information causing the charging abnormality.

5. The electric moving object of claim 4, further including:
an image acquisition unit configured to obtain a surround image of the electric moving object,
wherein the pairing misalignment information and the power transmission module abnormality information are provided as an image that estimates the misalignment and the abnormal situation based on the surround image which is obtained from the image acquisition unit during the charging operation.

6. The electric moving object of claim 5,
wherein the power transmission module unit includes a detector configured to detect the abnormal situation,
wherein the power transmission module unit is further configured to transmit, to the processor, abnormal situation data associated with presence of an object on the power transmission module unit, which is detected by the detector, and with an impact on the power transmission module unit caused by the object,
wherein the processor is further configured to identify the object from the surround image associated with the abnormal situation data, and
wherein the power transmission module abnormality information is provided as an image that estimates the abnormal situation based on the identified object.

7. The electric moving object of claim 3,
wherein the processor is further configured to display data associated with guide information resolving the stopping element on the user device, when resolving the stopping element in case of stop of charging due to the charging abnormality, and
wherein, when the stopping element is not resolved, the processor is further configured to display data associated with the charging obstacle information, which causes the charging failure, on the user device.

8. The electric moving object of claim 1, wherein the electric moving object is configured to transmit the data associated with the information on the charging situation to a server, and
wherein the user device is configured to receive the information on the charging situation, which is generated based on the data, from the server.

9. The electric moving object of claim 1, wherein, when the electric moving object enters a charging zone of the wireless charging device, the processor is further configured to:
maintain a predetermined distance to an object around the charging zone,
generate information on a charging location that realizes normal pairing between the power transmission module unit and the power reception module unit, and
provide the information on the charging location to any one of a display of the electric moving object and the user device.

10. The electric moving object of claim 9, wherein the information on the charging location is displayed to include a virtual charging park line where the electric moving object is parked within the charging zone.

11. A method for guiding a wireless charging situation of an electric moving object, the method comprising:
supplying power from a power transmission module unit of a wireless charging device to a power reception module unit of the electric moving object;
controlling, by a charging controller of the electric moving object, a charging operation, and generating data associated with information on a charging situation including charging progress information and charging obstacle information that occurs during a charging abnormality; and
transmitting, by a processor of the electric moving object, data associated with the information on the charging situation so that the data is displayed on a user device.

12. The method of claim 11, wherein the charging progress information includes charging state information, which includes a charging amount according to the charging operation, charging efficiency and an expected charging time, and pairing information between the power transmission module unit and the power reception module unit.

13. The method of claim 11, the charging obstacle information is information indicating an element that causes temporary stop of the charging operation or charging failure by the charging abnormality.

14. The method of 13, wherein the charging obstacle information includes at least one of pairing misalignment information indicating a misalignment based on location information of the power transmission module unit and the power reception module unit, pairing abnormality information caused by a poor pairing connection between the power transmission unit and the power reception unit, power transmission module abnormality information indicating an abnormal situation of the power transmission module unit, moving object abnormality information caused by a charging system abnormality of the electric moving object, power abnormality information according to power degradation of the wireless charging device, and external environment information causing the charging abnormality.

15. The method of claim 14, further including:
an image acquisition unit configured to obtain a surround image of the electric moving object,
wherein the pairing misalignment information and the power transmission module abnormality information are provided as an image that estimates the misalignment and the abnormal situation based on the surround image which is obtained from the image acquisition unit during the charging operation.

16. The method of claim 15, wherein the power transmission module unit includes a detector configured to detect the abnormal situation, and
after the supplying of the power, the method further includes,
transmitting, by the power transmission module unit, abnormal situation data associated with presence of an object on the power transmission module unit, which is detected by the detector, and with an impact on the power transmission module unit caused by the object to the processor; and
identifying, by the processor, the object from the surround image associated with the abnormal situation data, and
wherein the power transmission module abnormality information is provided as an image that estimates the abnormal situation based on the identified object.

17. The method of claim 13, wherein the transmitting of the data includes:
displaying, by the processor, data associated with guide information resolving a stopping element on the user device, when resolving the stopping element in case of stop of charging due to the charging abnormality; and
displaying, by the processor, data associated with the charging obstacle information causing charging failure on the user device, when the stopping element is not resolved.

18. The method of claim 11,
wherein the transmitting of the data further includes transmitting, by the electric moving object, the data associated with the information on the charging situation to a server, and
wherein, the user device is configured to receive the information on the charging situation, which is generated based on the data, from the server.

19. The method of claim 11, further including:
before the supplying of the power,
maintaining, by the processor, a predetermined distance to an object around the charging zone, when the electric moving object enters a charging zone of the wireless charging device,
generating information on a charging location that realizes normal pairing between the power transmission module unit and the power reception module unit; and
providing, by the processor, the information on the charging location to any one of a display of the electric moving object and the user device.

20. The method of claim 19, wherein the information on the charging location is displayed to include a virtual charging park line where the electric moving object is parked within the charging zone.
